(19) United States
(12) Patent Application Publication
(10) Pub. No.: US 2026/0226254 A1
(43) Pub. Date: Aug. 6, 2026

(54) STABILIZER COMPOSITIONS FOR HIGH CLARITY RANDOM POLYPROPYLENE COPOLYMER AND METHODS THEREOF

(71) Applicant: CYTEC INDUSTRIES INC., Lawrence, NJ (US)

(72) Inventors: Jerry Mon Hei ENG, Wilton, CT (US); Jian-Yang CHO, Easton, CT (US); Ram B. GUPTA, Stamford, CT (US); Parker RENEAU, Stamford, CT (US)

(73) Assignee: CYTEC INDUSTRIES INC., Lawrence, NJ (US)

(21) Appl. No.: 19/151,919

(22) PCT Filed: Jan. 30, 2024
(86) PCT No.: PCT/EP2024/052140

§ 371 Date: Jul. 29, 2025

Related U.S. Application Data
(60) Provisional application No. 63/442,302, filed on Jan. 31, 2023.

(51) Int. Cl. C08K 5/3492; C08J 5/18; C08K 5/00; C08K 5/134; C08K 5/3462; C08K 5/526; H10F 19/80

(52) U.S. Cl. CPC C08K 5/34926; C08J 5/18; C08K 5/005; C08K 5/1345; C08K 5/3462; C08K 5/3492; C08K 5/526; H10F 19/804; C08J 2323/14

(57) ABSTRACT

A stabilization composition for making a polymeric front sheet of a photovoltaic cell comprising i) a random polypropylene copolymer resin, ii) a stabilizing amount of an orthohydroxyphenyl triazine ultraviolet light absorber, iii) a stabilizing amount of at least one hindered amine light stabilizer and iv) a stabilizing amount of at least one antioxidant selected from a hindered phenol, a phosphite, a phosphonite or a mixture thereof.

### BACKGROUND

Photovoltaics have long been used in the field of electricity generation by way of semiconducting materials that possess a photovoltaic effect and convert light into electricity. The increase in efficiency of solar panels in photovoltaic systems has led to a demand for materials to prolong the life in the outdoor elements. As such, photovoltaic cells are typically present between protective layers that together form photovoltaic complexes. These protective layers are commonly known to be made of glass. Given their location, it is generally desirable that the top/front sheet has high transparency to the desired incident light to allow efficient transmission of sunlight into the photovoltaic cells.

Polypropylene resins are known to deteriorate over time after exposure to heat, light and/or oxygen. The deterioration is then accompanied by UV degradation and a decline in the performance of the material, typically presented as a change in its overall color and luster, as well as its transmittance. Mixtures of various light stabilizing additive components have been used to remedy these deficiencies, however the use of the additives in achieving the desired performance in all areas is an ongoing problem.

Therefore, there exists a need for polypropylene resins used for solar cells, especially for front transparent sheet, with stabilizing properties that can reduce the degradation in performance of the material but that also maintains the transparency and efficient transmission of the layers used in photovoltaic applications.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a stabilization composition for making a polymeric front sheet of a photovoltaic cell that includes i) a random polypropylene copolymer resin, ii) a stabilizing amount of an orthohydroxyphenyl triazine ultraviolet light absorber (TZN-UVA), iii) a stabilizing amount of at least one hindered amine light stabilizer (HALS) comprising a functional group according to Formula (II):

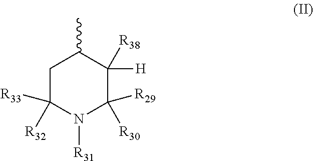

wherein R₃₁ is chosen from: H, OH, C₁-C₂₀ hydrocarbyl, —CH₂CN, C₁-C₁₂ acyl, or C₁-C₁₈ alkoxy; R₃₈ is chosen from: H or C₁-C₈ hydrocarbyl; and each of R₂₉, R₃₀, R₃₂, and R₃₃ is independently chosen from C₁-C₂₀ hydrocarbyl, or R₂₉ and R₃₀ and/or R₃₂ and R₃₃ taken together with the carbon to which they are attached form a C₅-C₁₀ cycloalkyl; or a functional group according to Formula (IIa):

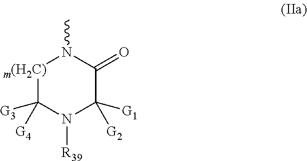

wherein m is an integer from 1 to 2; R₃₉ is chosen from: H, OH, C₁-C₂₀ hydrocarbyl; —CH₂CN; C₁-C₁₂ acyl; or C₁-C₁₈ alkoxy; and each of G₁-G₄ is independently chosen from C₁-C₂₀ hydrocarbyl; or mixtures of HALS compounds having functional groups according to Formula (II) and Formula (IIa) and iv) a stabilizing amount of at least one antioxidant selected from a hindered phenol, a phosphite, a phosphonite or a mixture thereof.

In another aspect, embodiments disclosed herein relate to a stabilized polymeric front sheet of a photovoltaic cell including a stabilization composition that includes i) a random polypropylene copolymer resin, ii) a stabilizing amount of an orthohydroxyphenyl triazine ultraviolet light absorber, iii) a stabilizing amount of at least one hindered amine light stabilizer comprising a function group according to Formula (II) or Formula (IIa) or mixtures of HALS compounds having functional groups according to Formula (II) and Formula (IIa) and iv) a stabilizing amount of at least one antioxidant selected from a hindered phenol, a phosphite, a phosphonite or a mixture thereof.

In another aspect, embodiments disclosed herein relate to a photovoltaic cell that includes a polymeric front sheet and a photovoltaic element, the polymeric front sheet including a stabilization composition comprising i) a random polypropylene copolymer resin, ii) a stabilizing amount of an orthohydroxyphenyl triazine ultraviolet light absorber, iii) a stabilizing amount of at least one hindered amine light stabilizer comprising a function group according to Formula (II) or Formula (IIa) or mixtures of HALS compounds having functional groups according to Formula (II) and Formula (IIa) and iv) a stabilizing amount of at least one antioxidant selected from a hindered phenol, a phosphite, a phosphonite or a mixture thereof.

In yet another aspect, embodiments disclosed herein relate to a method of making a stabilized polymeric front sheet of a photovoltaic cell that includes extruding or molding a stabilization composition that includes i) a random polypropylene copolymer resin, ii) a stabilizing amount of an orthohydroxyphenyl triazine ultraviolet light absorber, iii) a stabilizing amount of at least one hindered amine light stabilizer comprising a function group according to Formula (II) or Formula (IIa) or mixtures of HALS compounds having functional groups according to Formula (II) and Formula (IIa) and iv) a stabilizing amount of at least one antioxidant selected from a hindered phenol, a phosphite, a phosphonite or a mixture thereof.

Other aspects and advantages of the claimed subject matter will be apparent from the following description and the appended claims.

### BRIEF DESCRIPTION OF DRAWINGS

FIG. 1A shows microscope images from gas fade testing of a stabilized random polypropylene copolymer with stabilization composition comprising an LMW-HALS and a triazine UVA before (left) and after (right) gas fading.

FIG. 1B shows microscope images from gas fade testing of a stabilized random polypropylene copolymer with stabilization composition comprising an HMW-HALS and a LMW-HALS and a triazine UVA before (left) and after (right) gas fading.

FIG. 1C shows microscope images from gas fade testing of a stabilized random polypropylene copolymer with stabilization composition comprising a secondary HMW-HALS and a triazine UVA before (left) and after (right) gas fading.

FIG. 1D show microscope images from gas fade testing of a stabilized random polypropylene copolymer with stabilization composition comprising a tertiary HMW-HALS and a triazine UVA before (left) and after (right) gas fading.

### DETAILED DESCRIPTION

Embodiments disclosed herein are directed to the use of a stabilization composition in the formation of a polymeric high clarity front sheet of a photovoltaic cell. In order to overcome the technical barriers discussed above, the present disclosure provides a stabilization composition for use in solar cells, especially for stabilization of front transparent sheet, for photovoltaics with improved weathering resistance, UV stability and mechanical performance.

Embodiments disclosed herein relate to a stabilization composition comprising:
i.) a random polypropylene copolymer resin;
ii.) a stabilizing amount of an orthohydroxyphenyl triazine ultraviolet light absorber (TZN-UVA);
iii.) a stabilizing amount of at least one hindered amine light stabilizer (HALS); and
iv.) a stabilizing amount of at least one antioxidant selected from a hindered phenol, a phosphite, a phosphonite or a mixture thereof.

In the present disclosure, the total amount of all components of the composition add up to 100 wt % based on the total weight of the composition. Moreover, it is envisioned that the stabilization composition may be initially formulated as a masterbatch composition, in which the stabilizers and other additives may be present at higher concentrations than in a final formulation, where the masterbatch composition is diluted prior to formation into a shaped article.

In some embodiments, the stabilization composition may comprise random polypropylene copolymer resin in an amount ranging from 10 wt % to 99.99 wt %, based on the total weight of the composition. For example, the random polypropylene copolymer resin may be present in an amount ranging from a lower limit of any of 10, 20, 50, 75, 90, or 95 wt % to an upper limit of any of 50, 75, 90, 95, 98, 99, 99.5 or 99.99 wt % where any lower limit can be used in combination with any mathematically compatible upper limit. However, in one or more embodiments of the stabilization composition in a final formulation for formation of a shaped article, the random polypropylene copolymer resin may be present in an amount ranging from a lower limit of any of 90, 92, or 95 w % to an upper limit of any of 98, 99, 99.5 or 99.99 wt % where any lower limit can be used in combination with any mathematically compatible upper limit. In embodiments involving a masterbatch formulation, the random polypropylene copolymer resin may be present in lower concentrations, such as for example, at amounts lower than 80, 60, 50 wt %.

### Light Absorber

For the embodiments disclosed, a light absorber is provided to absorb electromagnetic radiation from a light source. In one or more embodiment, the light absorber may be an ultraviolent light absorber (UVA). In particular, the UV light absorber may include an orthohydroxyphenyl triazine. For example, in one or more embodiments, the ultraviolet light absorber is an orthohydroxyphenyl triazine (TZN-UVA) such as a 2-(2′-hydroxyphenyl)-1,3,5-triazine compound according to Formula (I),

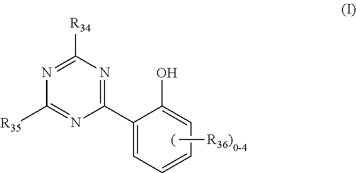

wherein R₃₄ and R₃₅ are the same or different and are independently chosen from a C₆-C₁₀ aryl group, wherein the C₆-C₁₀ aryl group is optionally substituted at from 1 to 3 substitutable positions with one or more group chosen from OH, halogen, C₁-C₁₂ alkyl, C₁-C₁₂ alkoxy, C₁-C₁₂ alkoxyester, C₂-C₁₂ alkanoyl, or phenyl, wherein the phenyl is optionally substituted at from 1 to 3 substitutable positions with one or more group chosen from: hydroxyl, halogen, C₁-C₁₂ alkyl, C₁-C₁₂ alkoxy, C₁-C₁₂ alkoxyester, or C₂-C₁₂ alkanoyl; mono- or di-C₁-C₁₂ hydrocarbyl-substituted amino; C₂-C₁₂ alkanoyl;C₁-C₁₂ alkyl;C₁-C₁₀ acyl; or C₁-C₁₀ alkoxyl; and R₃₆ is a substituent that is the same or different at from 0 to 4 positions of the phenoxy portion of Formula (I) and is independently chosen from hydroxyl, halogen, C₁-C₁₂ alkyl, C₁-C₁₂ alkoxy, C₁-C₁₂ alkoxyester, C₂-C₁₂ alkanoyl; phenyl; or C₁-C₁₂ acyl.

For example, in some embodiments, an orthohydroxyphenyl triazine ultraviolet light absorber (TZN-UVA) is a 2-(2′-hydroxyphenyl)-1,3,5-triazine compound may be selected from the group consisting of 4,6-bis-(2,4-dimethylphenyl)-2-(2-hydroxy-4-octyloxyphenyl)-s-triazine; 2-(4,6-Diphenyl-1,3,5-triazin-2-yl-)-5-((hexyl)oxyl-phenol; 4,6-bis-(2,4-dimethylphenyl)-2-(2,4-dihydroxyphenyl)-s-triazine; 2,4-bis(2,4-dihydroxyphenyl)-6-(4-chlorophenyl)-s-triazine; 2,4-bis[2-hydroxy-4-(2-hydroxy-ethoxy)phenyl]-6-(4-chlorophenyl)-s-triazine; 2,4-bis[2-hydroxy-4-(2-hydroxy-4-(2-hydroxy-ethoxy)phenyl]-6-(2,4-dimethylphenyl)-s-triazine; 2,4-bis[2-hydroxy-4-(2-hydroxyethoxy)phenyl]-6-(4-bromophenyl)-s-triazine; 2,4-bis[2-hydroxy-4-(2-acetoxyethoxy)phenyl]-6-(4-chlorophenyl)-s-triazine; 2,4-bis(2,4-dihydroxyphenyl)-6-(2,4-dimethylphenyl)-s-triazine; 2,4-bis(4-biphenylyl)-6-[2-hydroxy-4-[(octyloxycarbonyl)ethylideneoxy]phenyl]-s-triazine; 2,4-bis(4-biphenylyl)-6-[2-hydroxy-4-(2-ethylhexyloxy)phenyl]-s-triazine; 2-phenyl-4-[2-hydroxy-4-(3-sec-butyloxy-2-hydroxypropyloxy)phenyl]-6-[2-hydroxy-4-(3-sec-amyloxy-2-hydroxypropyloxy)phenyl]-s-triazine; 2,4-bis(2,4-dimethylphenyl)-6-[2-hydroxy-4(-3-benzyloxy-2-hydroxypropyloxy)phenyl]-s-triazine; 2,4-bis(2-hydroxy-4-n-butyloxyphenyl)-6-(2,4-di-n-butyloxyphenyl)-s-triazine; 2,4-bis(2,4-dimethylphenyl)-6-[2-hydroxy-4-(3-nonyloxy-2-hydroxypropyloxy)-5-α-cumylphenyl]-s-triazine; methylenebis-{2,4-bis(2,4-dimethylphenyl)-6-[2-hydroxy-4-(3-butyloxy-2-hydroxypropoxy)phenyl]-s-triazine}; methylene bridged dimer mixture bridged in the 3:5′,5:5′ and 3:3′ positions in a 5:4:1 ratio; 2,4,6-tris(2-hydroxy-4-isooctyloxycarbonyliso-propylideneoxy-phenyl)-s-triazine; 2,4,6,-tris(2-hydroxy-4-octyloxy-phenyl)-1,3,5-triazine; 2,4-bis(2,4-dimethylphenyl)-6-(2-hydroxy-4-hexyloxy-5-α-cumylphenyl)-s-triazine; 2-(2,4,6-trimethylphenyl)-4,6-bis[2-hydroxy-4-(3-butyloxy-2-hydroxypropyloxy)phenyl]-s-triazine; 2,4,6-tris[2-hydroxy-4-(3-sec-butyloxy-2-hydroxypropyloxy)-phenyl]-s-triazine; a mixture of 4,6-bis-(2,4-dimethylphenyl)-2-(2-hydroxy-4-(3-dodecyloxy-2-hydroxypropoxy)phenyl)-s-triazine and 4,6-bis-(2,4-dimethylphenyl)-2-(2-hydroxy-4-(3-tridecyloxy-2-hydroxypropoxy)phenyl)-s-triazine; 4,6-bis-(2,4-dimethylphenyl)-2-(2-hydroxy-4 (3-(2-ethylhexyloxy)-2-hydroxypropoxy)-phenyl)-s-triazine; 4,6-diphenyl-2-(4-hexyloxy-2-hydroxyphenyl)-s-triazine; and mixtures thereof.

In one or more embodiments, the stabilizing composition comprises a stabilizing amount of the aforementioned light absorber such as for example, an amount ranging from a lower limit of any of 0.01, 0.02, and 0.03 wt % to an upper limit of any of an 0.05, 0.1, and 0.3 wt %, where any lower limit can be used in combination with any upper limit. In embodiments involving a masterbatch formulation, the UV light absorber may be present in higher concentrations, such as for example, at amounts 0.5, 2.5, 5 wt % maximum.

In more than one embodiment, the stabilizing composition may comprise an additional ultraviolet light absorber selected from the group consisting of orthohydroxybenzophenones, orthohydroxyphenyl benzotriazoles, benzoxazinone; oxanilides, cyanoacrylates, and mixtures thereof.

However, in accordance with one or more embodiments, the additional ultraviolet light absorber is a orthohydroxybenzopheneone, the orthohydroxybenzopheneone compound may be selected from the group consisting of 2-hydroxy-4-methoxybenzophenone; 2,2′-dihydroxy-4-methoxybenzophenone; 2-hydroxy-4-octyloxybenzophenone; 2,2′-dihydroxy-4,4′-di-methoxybenzophenone; 2,2′-dihydroxybenzophenone; 2,2′,4,4′-tetrahydroxybenzophenone; 2,2′-dihydroxy-4,4′-dimethoxybenzophenone; 2,2′-dihydroxy-4,4′-diethoxybenzophenone; 2,2′-dihydroxy-4,4′-dipropoxybenzophenone; 2,2′-dihydroxy-4,4′-dibutoxybenzophenone; 2,2′-dihydroxy-4-methoxy-4′-ethoxybenzophenone; 2,2′-dihydroxy-4-methoxy-4′-propoxybenzophenone; 2,2′-dihydroxy-4-methoxy-4′-butoxybenzophenone; 2,2′-dihydroxy-4-ethoxy-4′-propoxybenzophenone; 2,2′-dihydroxy-4-ethoxy-4′-butoxybenzophenone; 2,3′-dihydroxy-4,4′-dimethoxybenzophenone; 2,3′-dihydroxy-4-methoxy-4′-butoxybenzophenone; 2-hydroxy-4,4′,5′-trimethoxybenzophenone; 2-hydroxy-4,4′,6′-tributoxybenzophenone; 2-hydroxy-4-butoxy-4′,5′-dimethoxybenzophenone; 2-hydroxy-4-ethoxy-2′,4′-dibutylbenzophenone; 2-hydroxy-4-propoxy-4′,6′-dichlorobenzophenone; 2-hydroxy-4-propoxy-4′,6′-dibromobenzophenone; 2,4-dihydroxybenzophenone; 2-hydroxy-4-ethoxybenzophenone; 2-hydroxy-4-propoxybenzophenone; 2-hydroxy-4-butoxybenzophenone; 2-hydroxy-4-methoxy-4′-methylbenzophenone; 2-hydroxy-4-methoxy-4′-ethylbenzophenone; 2-hydroxy-4-methoxy-4′-propylbenzophenone; 2-hydroxy-4-methoxy-4′-butylbenzophenone; 2-hydroxy-4-methoxy-4′-tertiary-butylbenzophenone; 2-hydroxy-4-methoxy-4′-chlorobenzophenone; 2-hydroxy-4-methoxy-2′-chlorobenzophenone; 2-hydroxy-4-methoxy-4′-bromobenzophenone; 2-hydroxy-4,4′-dimethoxybenzophenone; 2-hydroxy-4,4′-dimethoxy-3-methylbenzophenone; 2-hydroxy-4,4′-dimethoxy-2′-ethylbenzophenone; 2-hydroxy-4,4′,5′-trimethoxybenzophenone; 2-hydroxy-4-ethoxy-4′-methylbenzophenone; 2-hydroxy-4-ethoxy-4′-ethylbenzophenone; 2-hydroxy-4-ethoxy-4′-propylbenzophenone; 2-hydroxy-4-ethoxy-4′-butylbenzophenone; 2-hydroxy-4-ethoxy-4′-methoxybenzophenone; 2-hydroxy-4,4′-diethoxybenzophenone; 2-hydroxy-4-ethoxy-4′-propoxybenzophenone; 2-hydroxy-4-ethoxy-4′-butoxybenzophenone; 2-hydroxy-4-ethoxy-4′-chlorobenzophenone; 2-hydroxy-4-ethoxy-4′-bromobenzophenone; and mixtures thereof.

Moreover, in accordance with one or more embodiments, the additional ultraviolet light absorber may be a orthohydroxyphenyl benzotriazole compound, the orthohydroxyphenyl benzotriazole may be selected from the group consisting of 2-(2′-hydroxy-5′-methylphenyl)-benzotriazole; 2-(2′-hydroxy-5′-tert-butylphenyl)benzotriazole; 2-(2′-hydroxy-3′-methyl-5′-tert-butylphenyl)-benzotriazole; 2-(2′-hydroxy-5′-cyclohexylphenyl)-benzotriazole; 2-(2′-hydroxy-3′,5′-dimethylphenyl)-benzotriazole; 2-(2′-hydroxy-5′-tert-butylphenyl)-5-chloro-benzotriazole; 2-(2′-hydroxy-5-tert-octylphenyl)-2H-benzotriazole; 2-(2′-hydroxy-5-octylphenyl)-2H-benzotriazole; 2-(3′,5′-di-tert-butyl-2′-hydroxyphenyl)-5-chlorobenzotriazole; 2-(3′-tert-butyl-5′-methyl-butyl-2′hydroxyphenyl)-5-chlorobenzotriazole; 2-(3′,5′-di-tert-amyl-2′-hydroxyphenyl)benzotriazole; 2-(3′,5′-bis(α,α-dimethylbenzyl)-2′-hydroxyphenyl)benzotriazole; 2-(3′-tert-butyl-2′-hydroxy-5′-(2-octyloxycarbonylethyl)phenyl)benzotriazole; 2,2′-methylene-bis[4-(1,1,3,3-tetramethylbutyl)-6-benzotriazole-2-ylphenol]; the transesterification product of 2-[3′-tert-butyl-5′-(2-methoxycarbonylethyl)-2′-hydroxyphenyl]-2H-benzotriazole with polyethylene glycol 300; 2-[2′-hydroxy-3′-(α,α-dimethylbenzyl)-5′-(1,1,3,3-tetramethyl-butyl)phenyl]benzotriazole; 5-trifluoromethyl-2-(2-hydroxy-3-α-cumyl-5-tert-octylphenyl)-2H-benzotriazole; 2-(2′-hydroxy-5′-(2-hydroxyethyl)phenyl)benzotriazole; 2-(2′-hydroxy-5′-(2-methacryloyloxyethyl)phenyl)benzotriazole; 2-(3′-tert-butyl-5′-methyl-2′-hydroxyphenyl)-5-chloro-benzotriazole; 2-(3′-sec-butyl-5′-tert·butyl-2′-hydroxyphenyl)-benzotriazole; 2-(3′,5′-di-tert-butyl-2′-hydroxyphenyl)-benzotriazole; 2-(5′-tert-octyl-2′-hydroxyphenyl)-benzotriazole; 2-(3′-dodecyl-5′-methyl-2′-hydroxyphenyl)-benzotriazole; 2-(3′-tert-butyl-5′-(2-octyloxycarbonylethyl)-2′-hydroxyphenyl)-5-chlorobenzotriazole; 2-(5′-methyl-2′-hydroxyphenyl)-benzotriazole; 2-(5′-tert-butyl-2′-hydroxyphenyl)-benzotriazole; 2-(2′-hydroxy-3′-di-tert-butylphenyl)-benzotriazole; and mixtures thereof.

According to one or more embodiments, the additional ultraviolet light absorber may be a benzoxazinone compound, the benzoxazinone may be selected from the group consisting of 2-methyl-3,1-benzoxazin-4-one; 2-butyl-3,1-benzoxazin-4-one; 2-phenyl-3,1-benzoxazin-4-one; 2-(1- or 2-naphthyl)-3,1-benzoxazin-4-one; 2-(4-biphenyl)-3,1-benzoxazin-4-one; 2-p-nitrophenyl-3,1-benzoxazin-4-one; 2-m-nitrophenyl-3,1-benzoxazin-4-one; 2-p-benzoylphenyl-3,1-benzoxazin-4-one; 2-p-methoxyphenyl-3,1-benzoxazin-4-one; 2-O-methoxyphenyl-3,1-benzoxazin-4-one; 2-cyclohexyl-3,1-benzoxazin-4-one; 2-p-(or m-)phthalimidephenyl-3,1-benzoxazin-4-one; N-phenyl-4-(3,1-benzoxazin-4-one-2-yl)phthalimide; N-benzoyl-4-(3,1-benzoxazine-4-one-2-yl)aniline; N-benzoyl-N-methyl-4-(3,1-benzoxazin-4-one-2-yl)-aniline; 2-[p-(N-phenylcarbamonyl)phenyl]-3,1-benzoxazin-4-one; 2-[p-(N-phenyl N-methylcarbamoyl)phenyl]-3,1-benzoxazin-4-one; 2,2′-bis(3,1-benzoxazin-4-one); 2,2′-ethylenebis(3,1-benzoxazin-4-one); 2,2′-tetramethylenebis(3,1-benzoxazin-4-one); 2,2′-hexamethylenebis(3,1-benzoxazin-4-one); 2,2′-decamethylenebis(3,1-benzoxazin-4-one); 2,2′-p-phenylenebis(3,1-benzoxazin-4-one); 2,2′-m-phenylenebis(3,1-benzoxazin-4-one); 2,2′-(4,4′-diphenylene)bis(3,1-benzoxazin-4-one); 2,2′-(2,6- or 1,5-naphthalene)bis(3,1-benzoxazin-4-one); 2,2′-(2-methyl-p-phenylene)bis(3,1-benzoxazin-4-one); 2,2′-(2-nitro-p-phenylene)bis(3,1-benzoxazin-4-one); 2,2′-(2-chloro-p-phenylene)bis(3,1-benzoxazin-4-one); 2,2′-(1,4-cyclohexylene)bis(3,1-benzoxazin-4-one); N-p-(3,1-benzoxazin-4-on-2-yl)phenyl; 4-(3,1-benzoxazin-4-on-2-yl)phthalimide; N-p-(3,1-benzoxazin-4-on-2-yl)benzoyl; 4-(3,1-benzoxazin-4-on-2-yl)aniline; 1,3,5-tri(3,1-benzoxazin-4-on-2-yl)benzene; 1,3,5-tri(3,1-benzoxazin-4-on-2-yl)naphthalene; and 2,4,6-tri(3,1-benzoxazin-4-on-2-yl)naphthalene.

In one or more embodiments, the stabilizing composition comprises an amount of the aforementioned additional ultraviolet light absorber such as for example, an amount ranging from a lower limit of any 0.01, 0.1, and 0.2 wt % to an upper limit of a 0.5, 0.75 and 1.0%, where any lower limit can be used in combination with any upper limit. In embodiments involving a masterbatch composition, the additional UV light absorber may be present in higher concentrations, such as for example, at amounts 0.5, 2.5, 5 wt % maximum.

### Hindered Amine Light Stabilizers (HALS)

For the embodiments described herein, hindered amine light stabilizers may include low molecular weight hindered amine light stabilizers (LMW-HALS) that have a molecular weight of less than 1000 g/mol and high molecular weight hindered amine light stabilizers (HMW-HALS) that have a molecular weight of greater than or equal to 1000 g/mol. Furthermore, the amines of the molecular weight ranges may include secondary amines, tertiary amines, or combinations thereof.

In one or more embodiment, the stabilizing composition may comprise a stabilizing amount of at least one hindered amine light stabilizer (HALS) comprising a functional group according to Formula (II),

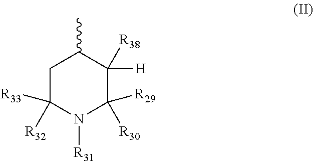

wherein R₃₁ is chosen from: H, OH, C₁-C₂₀ hydrocarbyl, —CH₂CN, C₁-C₁₂ acyl, or C₁-C₁₈ alkoxy; R₃₈ is chosen from: H or C₁-C₈ hydrocarbyl; and each of R₂₉, R₃₀, R₃₂, and R₃₃ is independently chosen from C₁-C₂₀ hydrocarbyl, or R₂₉ and R₃₀ and/or R₃₂ and R₃₃ taken together with the carbon to which they are attached form a C₅-C₁₀ cycloalkyl; or a functional group according to Formula (IIa):

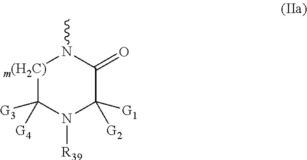

wherein m is an integer from 1 to 2; R₃₉ is chosen from: H, OH, C₁-C₂₀ hydrocarbyl; —CH₂CN; C₁-C₁₂ acyl; or C₁-C₁₈ alkoxy; and each of G₁-G₄ is independently chosen from C₁-C₂₀ hydrocarbyl; or mixtures of HALS compounds having functional groups according to Formula (II) and Formula (IIa);

In at least one embodiment, the stabilizing composition may comprise a stabilizing amount of at least one hindered amine light stabilizer (HALS) selected from a high molecular weight hindered amine light stabilizers (HMW-HALS).

In another preferred embodiment, the stabilizing composition comprises HALS selected only from high molecular weight hindered amine light stabilizer (HMW-HALS) having a weight average molecular weight of greater than 1000 g/mol. That is, in one or more embodiments, the HALS consist of the HMW-HALS.

In at least one embodiment, the at least one hindered amine light stabilizer may be a HMW-HALS selected from the group consisting of: a condensate of 1-(2-hydroxyethyl)-2,2,6,6-tetramethyl-4-hydroxypiperidine and succinic acid; 2,2,6,6-tetramethylpiperidin-4-yl stearate; a condensate of N,N′-bis(2,2,6,6-tetramethylpiperidin-4-yl)hexamethylenediamine and 4-tert-octylamino-2,6-dichloro-1,3,5-triazine; tetrakis(2,2,6,6-tetramethylpiperidin-4-yl)-1,2,3,4-butanetetracarboxylate; a condensate of N,N′-bis(2,2,6,6-tetramethylpiperidin-4-yl)hexamethylenediamine and 4-morpholino-2,6-dichloro-1,3,5-triazine; a condensate of N,N′-bis(2,2,6,6-tetramethylpiperidin-4-yl)hexamethylenediamine and 4-morpholino-2,6-dichloro-1,3,5-triazine, methylated; a condensate of 2-chloro-4,6-bis(4-n-butylamino-2,2,6,6-tetramethylpiperidyl)-1,3,5-triazine and 1,2-bis(3-aminopropylamino)ethane; a condensate of 2-chloro-4,6-bis(4-n-butylamino-1,2,2,6,6-pentamethylpiperidyl)-1,3,5-triazine and 1,2-bis-(3-aminopropylamino)ethane; a condensate of N,N′-bis(2,2,6,6-tetramethylpiperidin-4-yl)hexamethylenediamine and 4-cyclohexylamino-2,6-dichloro-1,3,5-triazine; a condensate of 1,2-bis(3-aminopropylamino)ethane, 2,4,6-trichloro-1,3,5-triazine and 4-butylamino-2,2,6,6-tetramethylpiperidine; oxo-piperanzinyl-triazines; 1,2,3,4-butanetetracarboxylic acid, polymer with 2,2,6,6-tetramethyl-2,4,8,10-tetraoxaspiro[5.5]-undecane-3,9-diethanol, 1,2,2,6,6-pentamethyl-4-piperdinyl ester; 1,2,3,4-butanetetracarboxylic acid, polymer with 2,2,6,6-tetramethyl-2,4,8,10-tetraoxaspiro[5.5]-undecane-3,9-diethanol, 2,2,6,6-tetramethyl-4-piperdinyl ester; bis(1-undecanoxy-2,2,6,6-tetramethylpiperidin-4-yl) carbonate; a reaction product of 1-(2-hydroxyethyl)-2,2,6,6-tetramethyl-4-piperdinol and dimethylsuccinate; 2,2,4,4-tetramethyl-7-oxa-3,20-diazadispiro[5.1.11.2]heneicosan-21-one; 1H-Pyrrole-2,5-dione, 1-octadecyl-, polymer with (1-methylethenyl)benzene and 1-(2,2,6,6-tetramethyl-4-piperidinyl)-1H-pyrrole-2,5-dione; the reaction product of 7,7,9,9-tetramethyl-2-cycloundecyl-1-oxa-3,8-diaza-4-oxospiro[4.5]decane and epichlorohydrin; the condensate of N,N′-bis(2,2,6,6-tetramethylpiperidin-4-yl)hexamethylenediamine and 4-cyclohexylamino-2,6-dichloro-1,3,5-triazine; the condensate of 1,2-bis(3-aminopropylamino)ethane, 2,4,6-trichloro-1,3,5-triazine and 4-butylamino-2,2,6,6-tetramethylpiperidine; the condensate of N,N′-bis(2,2,6,6-tetramethylpiperidin-4-yl)hexamethylenediamine and 4-morpholino-2,6-dichloro-1,3,5-triazine; the condensate of 2-chloro-4,6-bis(4-n-butylamino-2,2,6,6-tetramethylpiperidyl)-1,3,5-triazine and 1,2-bis(3-aminopropylamino)ethane; the condensate of 2-chloro-4,6-bis(4-n-butylamino-1,2,2,6,6-pentamethylpiperidyl)-1,3,5-triazine and 1,2-bis-(3-aminopropylamino)ethane; 2-[(2-hydroxyethyl)amino]-4,6-bis[N-(1-cyclohexyloxy-2,2,6,6-tetramethylpiperidin-4-yl)butylamino-1,3,5-triazine; the condensate of 1-(2-hydroxyethyl)-2,2,6,6-tetramethyl-4-hydroxypiperidine and succinic acid; the condensate of N,N′-bis(2,2,6,6-tetramethylpiperidin-4-yl)hexamethylenediamine and 4-tert-octylamino-2,6-dichloro-1,3,5-triazine; copolymer of methylmethacrylate with ethyl acrylate and 2,2,6,6-tetramethylpiperidin-4-yl acrylate; copolymer of mixed C₂₀ to C₂₄ alpha-olefins and (2,2,6,6-tetramethylpiperidin-4-yl) succinimide; 1,2,3,4-butanetetracarboxylic acid, polymer with β,β,β′,β′-tetramethyl-2,4,8,10-tetraoxaspiro[5.5]undecane-3,9-diethanol, 1,2,2,6,6-pentamethyl-4-piperidinyl ester; 1,2,3,4-butanetetracarboxylic acid, polymer with β,β,β′,β′-tetramethyl-2,4,8,10-tetraoxaspiro[5.5]undecane-3,9-diethanol, 2,2,6,6-tetramethyl-4-piperidinyl ester copolymer; and mixtures thereof.

In one or more embodiments, the stabilizing composition comprises a stabilizing amount of the aforementioned hindered amine light stabilizer such as for example, an amount ranging from a lower limit of any of 0.05, 0.075, or 0.1 wt % to an upper limit of any of an 0.25, 0.5, or 1 wt %, where any lower limit can be used in combination with any upper limit. In embodiments involving a masterbatch composition, hindered amine light stabilizer may be present in higher concentrations, such as for example, at amounts 2.5, 10, 20 wt % maximum.

Within the hindered amine light stabilizer, in one or more embodiments, it may include both low molecular weight and high molecular weight hindered amine light stabilizer, while one or more other embodiments are 100% high molecular weight hindered amine light stabilizer.

### Antioxidants

In more than one embodiment, the stabilizing composition may comprise a stabilizing amount of at least one antioxidant. The antioxidant may be selected from a group consisting of a hindered phenol, a phosphite, a phosphonite, or mixtures thereof.

In at least one embodiment, suitable hindered phenol antioxidants for the stabilizing composition may be (1,3,5-tris(4-t-butyl-3-hydroxy-2,6-dimethylbenzyl)-1,3,5-triazine-2,4,6-(1H,3H,5H)-trione; 1,3,5-tris(3,5-di-tert-butyl-4-hydroxybenzyl)-1,3,5-triazine-2,4,6 (1H,3H,5H)-trione; 1,1,3-tris(2′-methyl-4′-hydroxy-5′-t-butylphenyl)butane; triethylene glycol bis[3-(3-t-butyl-4-hydroxy-5-methylphenyl)propionate]; 4,4′-thiobis(2-t-butyl-5-methylphenol); 2,2′-thiodiethylene bis[3-(3-t-butyl-4-hydroxyl-5-methylphenyl)propionate]; octadecyl 3-(3′-t-butyl-4′-hydroxy-5′-methylphenyl)propionate; tetrakismethylene(3-t-butyl-4-hydroxy-5-methylhydrocinnamate)methane; N,N′-hexamethylene bis[3-(3-t-butyl-4-hydroxy-5-methylphenyl)propionamide]; di(4-tertiarybutyl-3-hydroxy-2,6-dimethyl benzyl) thiodipropionate; and octadecyl 3,5-di-(tert)-butyl-4-hydroxyhydrocinnamate.

In some embodiments, the antioxidant may be an organic phosphite or phosphonite, for example, a triphenyl phosphite; a diphenyl alkyl phosphite; a phenyl dialkyl phosphite; trilauryl phosphite; trioctadecyl phosphite; distearyl pentaerythritol phosphite; tris(2,4-di-tert-butylphenyl) phosphite; tris(nonylphenyl) phosphite; a compound of any of the formulae (A), (B), (C), (D), (E), (F), (G), (H), (J), (K), and (L):

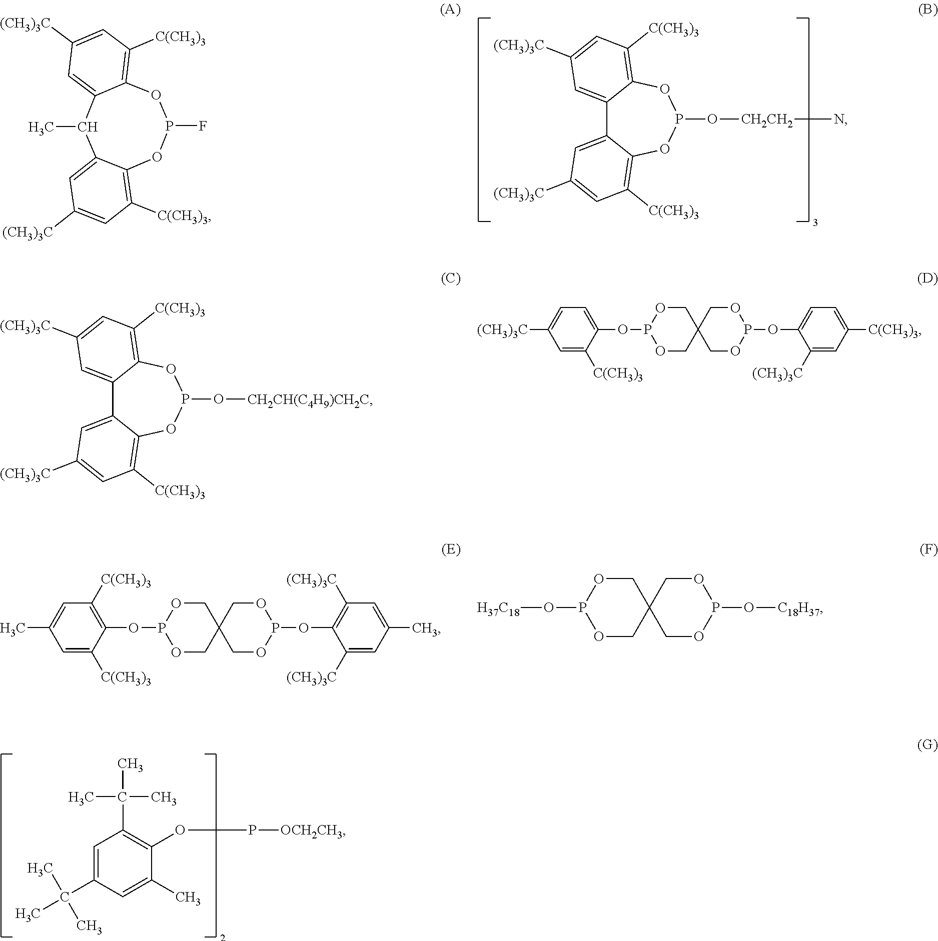

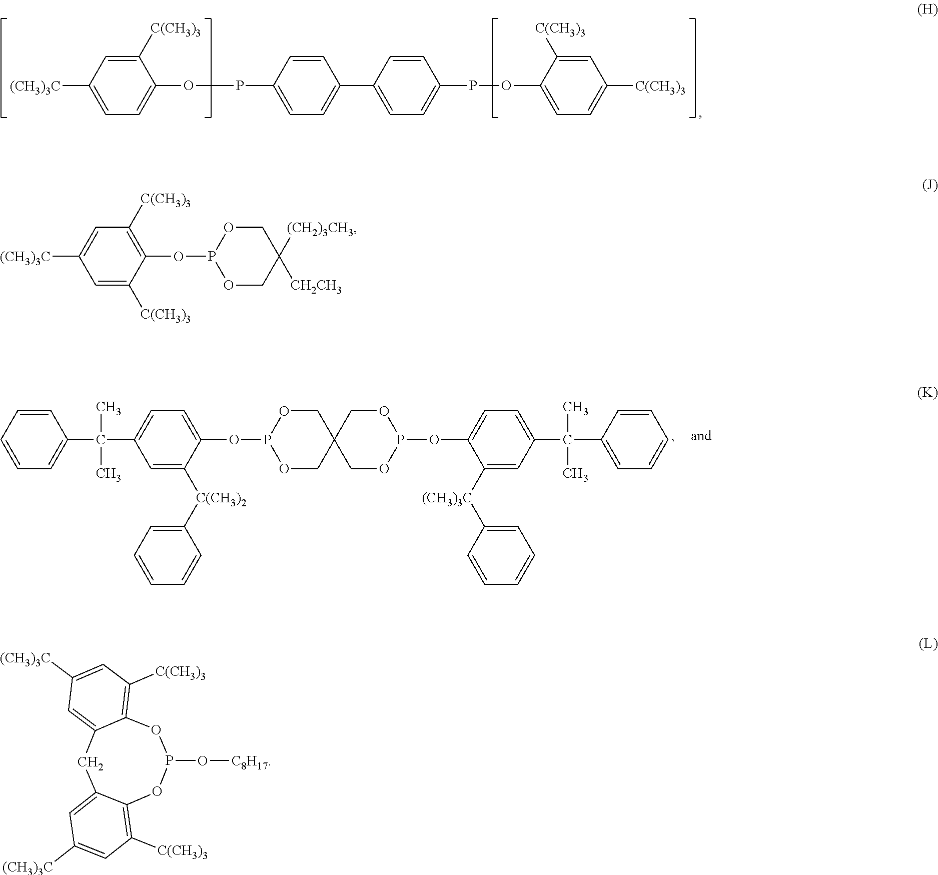

and 2-butyl-2-ethyl-1,3-propanediol 2,4,6-tri-t-butylphenol phosphite, bis-(2,6-di-t-butyl-4-methlphenyl) pentaerythritol diphosphite, 2-butyl-2-ethyl-1,3-propanediol 2,4-di-cumylphenol phosphite, 2-butyl-2-ethyl-1,3-propanediol 4-methyl-2,6-di-t-butylphenol phosphite, and bis-(2,4,6-tri-t-butyl-phenyl) pentaerythritol diphosphite, tris(2,4-di-tert-butylphenyl)phosphite (IRGAFOS® 168); bis(2,4-dicumylphenyl) pentaerythritol diphosphite ((DOVERPHOS® S9228); and tetrakis(2,4-di-tert-butylphenyl)4,4′-biphenylene-diphosphonite (IRGAFOS® P-EPQ).

In addition to the aforementioned components, the stabilization composition may further comprise a co-stabilizer. In at least one embodiment, the stabilization composition may comprise a co-stabilizer that may be a hindered benzoate or benzamide compound according to formula (VII):

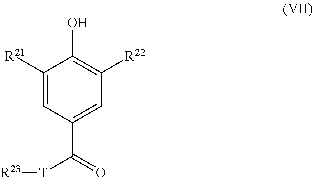

wherein each of R²¹ and R²² is independently chosen from a C₁-C₁₂ alkyl; T is chosen from O or NR²⁴, where R²⁴ is H or a C₁-C₃₀ hydrocarbyl; and R₂₃ is H or a C₁-C₃₀ hydrocarbyl.

In at least one embodiment, the stabilization composition may comprise a hindered benzoate as a co-stabilizer, examples selected from a group consisting of 2,4-di-tert-butylphenyl-3,5-di-tert-butyl-4-hydroxybenzoate; hexadecyl-3,5-di-tert-butyl-4-hydroxybenzoate; octadecyl-3,5-di-tert-butyl-4-hydroxybenzoate; octyl-3,5-di-tert-butyl-4-hydroxybenzoate; decyl-3,5-di-tert-butyl-4-hydroxybenzoate; dodecyl-3,5-di-tert-butyl-4-hydroxybenzoate; tetradecyl-3,5-di-tert-butyl-4-hydroxybenzoate; behenylyl-3,5-di-tert-butyl-4-hydroxybenzoate; 2-methyl-4,6-di-tert-butylphenyl-3,5-di-tert-butyl-4-hydroxybenzoate; butyl-3-[3-t-butyl-4-(3,5-di-t-butyl-4-hydroxybenzoyloxy)phenyl]propionate; and mixtures thereof.

In one or more embodiments, the stabilizing composition comprises a stabilizing amount of the aforementioned antioxidants (total antioxidants) such as for example, an amount ranging from a lower limit of any of 0.01, 0.05, 0.07, 0.1, or 0.2 wt % to an upper limit of any of 0.8, 1.25, or 2.25 wt %, where any lower limit can be used in combination with any upper limit. In embodiments involving a masterbatch composition, antioxidants may be present in higher concentrations, such as for example, at amounts greater than greater than 4, 15 or 30 wt % maximum.

In one or more embodiments, the stabilizing composition comprises hindered phenol antioxidants in an amount ranging from a lower limit of any of 0.01, 0.02, or 0.05 wt %, to an upper limit of any of 0.15, 0.2, or 0.25 wt %, where any lower limit can be used in combination with any upper limit. In embodiments involving a masterbatch composition, hindered phenol anti-oxidants may be present in higher concentrations, such as for example, at amounts 2, 7.5 or 15 wt % maximum.

In one or more embodiments, the stabilizing composition comprises phosphites and/or phosphonites antioxidants in an amount ranging from a lower limit of any of 0.01, 0.02, or 0.05 wt %, to an upper limit of any of 0.25, 0.5, or 1 wt %, where any lower limit can be used in combination with any upper limit. In embodiments involving a masterbatch composition, phosphites and/or phosphonites may be present in higher concentrations, such as for example, at amounts 2, 7.5 or 15 wt % maximum.

In one or more embodiments, the stabilizing composition comprises hindered benzoates antioxidants in an amount ranging from a lower limit of any of 0.05, 0.07, or 0.1 wt %, to an upper limit of any of 0.4, 0.5, or 1 wt %, where any lower limit can be used in combination with any upper limit. In embodiments involving a masterbatch composition, hindered benzoates may be present in higher concentrations, such as for example, at amounts 3, 15, 25 wt % maximum.

### Co-Additives

In more than one embodiment, the stabilization composition may further comprise one or more co-additives and mixtures thereof. Co-additives such as ones selected from a group consisting of nucleating agents, fillers, thioesters, hydroxylamines, metallic stearates, metal oxides, reinforcing agents, plasticizers, lubricants, rheology agents, catalysts, leveling agents, optical brighteners, anti-static agents, blowing agents, flame retardants, and mixtures thereof, may be suitable for use in more than one embodiment.

In one or more embodiments, the stabilizing composition optionally comprises such additives in an amount up to 5, 4, 3, 2, or 1 wt %. In embodiments involving a masterbatch composition, co-additives may be present in higher concentrations, such as for example, at amounts 1, 5 or 10 wt % maximum.

As noted above, according to some embodiments, the stabilization composition may be a concentrated mixture to be used as masterbatch and diluted with further amounts of the random polypropylene copolymer and optionally any of the above additives, including stabilizers prior to subsequent processes. In one or more embodiments, the masterbatch stabilization composition comprises random polypropylene copolymer in an amount of 10 to 95%, and the combined amount of the above additives, including light stabilizers, ranges from 5% to 90%.

### Photovoltaic Components

As mentioned above, the compositions of the present disclosure may be used to form an element of a photovoltaic cell, such as a front sheet of a photovoltaic cell. The stabilized polymeric high clarity front sheet of a photovoltaic cell may comprise a total stabilizers content ranging from 0.01 wt % to 10 wt %, preferably from 0.02 wt % to 5 wt %, more preferably from 0.02 wt % to 2 wt %, based on the total weight of the polymeric front sheet, wherein the total stabilizers content is the sum of the wt % content of the light stabilizing UV absorbers, the hindered amine light stabilizers, and any of the stabilizing additives and other co-additives as above-described, with a balance of the random polypropylene copolymer resin.

The disclosure also relates to a method of preparing a stabilized polymeric high clarity front sheet of a photovoltaic cell comprising the stabilization composition as above-described. The front sheet polymeric layer elements may be produced for example by extrusion, such as by cast film extrusion, using a conventional extruder and film formation equipment, or by molding such as injection molded. If is also envisioned that the front sheet may be a multilayer element. When such multilayers are used, it is understood that they may be coextruded or laminated.

In one or more embodiments, the front sheet may possess enhanced gas fading resistance leading to better color, better transparency and higher energy generation. The better weathering performance leads to longer life cycle for the solar cell.

The photovoltaic cells of the present disclosure may include a front sheet (formed from the present compositions), a photovoltaic cell surrounded or encapsulated by a light transmitting protective encapsulant, a back sheet element, and optionally a protective cover, like a metal frame. While the compositions are described as being used to form front sheets, it is also envisioned that the compositions may be used alone or in combination with other polymers to prepare other photovoltaic cell components, including but not limited to back sheets and encapsulant polymers.

The different elements of the photovoltaic cell or module are typically assembled together by conventional means to produce the final photovoltaic cell or module. Elements can be provided separately or partly in integrated form to such assembly step. The different elements are then typically attached together by lamination using the conventional lamination techniques in the field.

### EXAMPLES

The examples demonstrate the UV weathering and gas fading performance of stabilized random polypropylene copolymer compositions.

The commercially available materials used are shown in Table 1. The materials were incorporated with high clarity random polypropylene copolymers (Pro-fax Sr549M from Lyondell Basell Industries, referred to as Resin A, and RP 350 from Braskem, identified as Resin B) and processed using conventional single-screw extrusion with a temperature profile of 210° C.-220° C. After processing, standard 2×2.5×0.125 inch plaques were then injection molded using an Engel injection molding machine. The conditions during injection 10 molding were under standard injection molding procedure. All additives were used as received.

TABLE 1

| Sample Name | Chemical Name | Supplier |
|---|---|---|
| TINUVIN ® | Phenol, 2-(5-chloro-2H-benzotriazole-2-yl)-6- | BASF |
| 326 | (1,1-dimethylethyl)-4-methyl- | |
| Irgafos ® 168 | Tris(2,4-ditert-butylphenyl)phosphite | BASF |
| IRGANOX ® | Pentaerythritol tetrakis[3-(3′,5′-di-tert-butyl-4′- | BASF |
| 1010 | hydroxyphenyl)propionate] | |
| Chimassorb ® | N,N′,N″,N′″-tetrakis(4,6-bis(butyl-(N-methyl- | BASF |
| 119 | 2,2,6,6-tetramethylpiperidin-4-yl)amino)triazin- | |
| | 2-yl)-4,7-diazadecane-1,10-diamine | |
| CYASORB ® | 2-[4,6-bis(2,4-dimethylphenyl)-1,3,5-triazin-2- | Syensqo |
| UV-1164 | yl]-5-(octyloxy) phenol | |
| CYASORB ® | Substituted amine oligomer (1,6- | Syensqo |
| UV-3346 | hexanediamine, N,N′-bis(2,2,6,6-tetramethyl-4- | |
| | piperidinyl)-, polymers with morpholine-2,4,6- | |
| | trichloro-1,3,5-triazine reaction products | |
| CYASORB ® | mixture of 4-hexadecyloxy- and 4-stearyloxy- | Syensqo |
| UV-3853 | 2,2,6,6-tetramethylpiperidine | |
| CYASORB ® | 3,5-di-[t-butyl]-4-hydroxybenzoic acid | Syensqo |
| UV-2908 | hexadecyl ester | |

### Testing Methods:

Samples were exposed to fumes of combustion at 60° C.-65° C. and rotated using a carousel for gas fading testing. For oven aging, samples were exposed to 80° C. in a standard forced air convection Blue M oven. For UV weathering, samples were exposed to an Accelerated Weathering Tester QUV-313 under ASTM G154 conditions. Changes in color (delta E or ΔE) and in Yellowness Index (delta YI or ΔYI) of the samples are used to measure discoloration. Gloss values (60°) and YI, ΔE values were measured at incremental exposure intervals for all tests. High gloss values indicate a smooth surface while low gloss values can indicate phenomena such as surface crazing or additive migration. The higher the ΔE, the more the color change or discoloration of sample from the initial state. The higher the YI, the more yellow the samples become.

The prepared samples and their stabilizer compositions are shown in Table 2. The stabilizer composition is combined with Resin A and/or B, as noted below.

TABLE 2

| | Formulation | |
|---|---|---|
| Sample No. | Comprising | Composition |
| Comparative | Benzotriazole | 0.02% TINUVIN ® UV-326 + 0.064% |
| Sample - 1 | UVA | Chimassorb ® 119 + 0.064% |
| (CS1) | | CYASORB ® UV-3853 + 0.15% |
| | | CYASORB ® UV-2908 + 0.1% |
| | | Irganox ® 1010 + 0.1% Irgafos ® 168 |
| S2 | Triazine UVA | 0.02% CYASORB ® UV-1164 + 0.064% |
| | | Chimassorb ® 119 + 0.064% |
| | | CYASORB ® UV-3853 + 0.15% |
| | | CYASORB ® UV-2908 + 0.1% |
| | | Irganox ® 1010 + 0.1% Irgafos ® 168 |
| S3 | Tertiary | 0.02% CYASORB ® UV-1164 + 0.13% |
| | HWM-HALS | Chimassorb ®119 + 0.15% CYASORB ® |
| | | UV-2908 + 0.1% Irganox ® 1010 + 0.1% |
| | | Irgafos ® 168 |
| Comparative | LMW-HALS | 0.02% CYASORB ® UV-1164 + 0.13% |
| Sample - 4 | | CYASORB ® UV-3853 + 0.15% |
| (CS4) | | CYASORB ® UV-2908 + 0.1% |
| | | Irganox ® 1010 + 0.1% Irgafos ® 168 |
| S5 | Secondary | 0.02% CYASORB ® UV-1164 + 0.13% |
| | HMW-HALS | CYASORB ® UV-3346 + 0.15% |
| | | CYASORB ® UV-2908 + 0.1% |
| | | Irganox ® 1010 + 0.1% Irgafos ® 168 |
| Comparative | Secondary | 0.02% CYASORB ® UV-1164 + 0.064% |
| Example - 6 | HMW-HALS + | CYASORB ® UV-3346 + 0.064% |
| (CS6) | LMW-HALS | CYASORB ® UV-3853 + 0.15% |
| | | CYASORB ® UV-2908 + 0.1% |
| | | Irganox ® 1010 + 0.1% Irgafos ® 168 |

### Weathering Performance of Stabilized Random Polypropylene Copolymers

All formulations were compounded on a single screw extruder and injection molded into plaques. These plaques were exposed to the Accelerated Weathering Tester QUV-313 under ASTM G-154 conditions. Color data was collected in intervals. As shown in Table 3, the benzotriazole-containing samples (CS1A and CS1B) shows a much stronger color development during QUV-313 weathering. The triazine UVA-containing samples (S2A and S2B) show better weathering performance (lower total color change) in both random polypropylene copolymers.

TABLE 3

| Sample | 1000 hr ΔE | 200 hr ΔE |
|---|---|---|
| CS1A | 9.80 | — |
| S2A | 6.64 | — |
| CS1B | — | 12.04 |
| S2B | — | 9.24 |

### Gas Fade Testing of Stabilized Random Polypropylene Copolymers

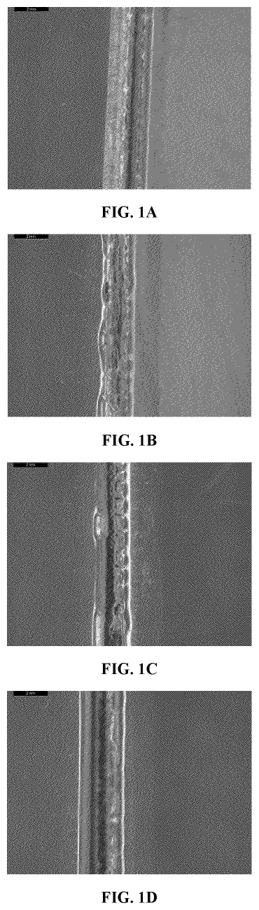

All formulations were compounded on a single screw extruder and injection molded into plaques. These plaques were exposed to fumes of combustion at 60-65° C. Gloss data was collected in intervals. As shown in Table 4 and FIG. 1A to FIG. 1D, low molecular weight hindered amine light stabilizing containing samples, alone or in combination with high molecular weight hindered amine light stabilizers, show adverse additive migration effects resulting in gloss reduction in the gas fade test in both random polypropylene copolymer resins.

TABLE 4

| | 0 hr 60° | 72 hr 60° | 168 hr 60° |
|---|---|---|---|
| Sample | Gloss | Gloss | Gloss |
| CS4A | 95.30 | — | 18.90 |
| CS6A | 95.40 | — | 13.45 |
| S5A | 95.40 | — | 73.65 |
| S3A | 95.05 | — | 72.45 |
| CS4B | 99.90 | 31.70 | — |
| CS6B | 100 | 30.40 | — |
| S5B | 100 | 67.25 | — |
| S3B | 99.85 | 69.75 | — |

As shown in Table 5, all resin A formulations containing low molecular weight hindered amine light stabilizing containing samples, alone or in combination with high molecular weight hindered amine light stabilizers, develop stronger color than both the tertiary and secondary HMW-HALS containing samples after 168 hr gas exposure.

TABLE 5

| Sample | 0 hr YI | 168 hr YI |
|---|---|---|
| CS4A | 9.0 | 14.21 |
| CS6A | 9.18 | 14.27 |
| S5A | 9.29 | 12.42 |
| S3A | 9.08 | 10.25 |

As shown in Table 6, all samples containing low molecular weight hindered amine light stabilizing containing samples, alone or in combination with high molecular weight hindered amine light stabilizers, develop stronger total color than the sample containing only high molecular weight hindered amine light stabilizer after 1000 hr QUV-313 exposure.

TABLE 6

| Sample | 1000 hr ΔE |
|---|---|
| CS4A | 6.96 |
| CS6A | 7.81 |
| S3A | 5.58 |

Advantageously, the stabilization compositions of the present disclosure may allow for a polypropylene-based composition that can be exposed to weather and other outdoor elements that can have reduced impact on transparency and clarity of the polypropylene resin. That is, while front sheets of photovoltaic cells are conventionally made of glass, the stabilization compositions of the present disclosure may allow for polypropylene-based compositions to be used in place of glass and possess the needed properties for the lifespan of the photovoltaic cells.

While the scope of the composition and method will be described with several embodiments, it is understood that one of ordinary skill in the relevant art will appreciate that many examples, variations and alterations to the composition and methods described here are within the scope and spirit of the disclosure. Accordingly, the embodiments described are set forth without any loss of generality, and without imposing limitations, on the disclosure. Those of skill in the art understand that the scope includes all possible combinations and uses of particular features described in the specifications.

1. A stabilization composition for making a polymeric front sheet of a photovoltaic cell comprising:
i) a random polypropylene copolymer resin;
ii) a stabilizing amount of an orthohydroxyphenyl triazine ultraviolet light absorber (TZN UVA);
iii) a stabilizing amount of at least one hindered amine light stabilizer (HALS) comprising a functional group according to Formula (II): 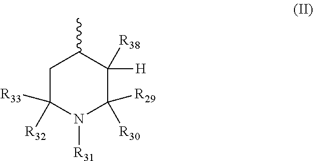
wherein R₃₁ is chosen from: H, OH, C₁-C₂₀ hydrocarbyl, —CH₂CN, C₁-C₁₂ acyl, or C₁-C₁₈ alkoxy; R₃₈ is chosen from: H or C₁-C₈ hydrocarbyl; and each of R₂₉, R₃₀, R₃₂, and R₃₃ is independently chosen from C₁-C₂₀ hydrocarbyl, or R₂₉ and R₃₀ and/or R₃₂ and R₃₃ taken together with the carbon to which they are attached form a C₅-C₁₀ cycloalkyl; or
a functional group according to Formula (IIa): 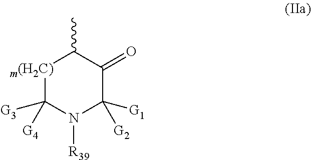
wherein
m is an integer from 1 to 2;
R₃₉ is chosen from: H, OH, C₁-C₂₀ hydrocarbyl;—CH₂CN; C₁-C₁₂ acyl; or C₁-C₁₈ alkoxy; and
each of G₁-G₄ is independently chosen from C₁-C₂₀ hydrocarbyl; or
mixtures of HALS compounds having functional groups according to Formula (II) and Formula (IIa);
iv) a stabilizing amount of at least one antioxidant selected from a hindered phenol, a phosphite, a phosphonite or a mixture thereof.

2. The stabilization composition according to claim 1, wherein the orthohydroxyphenyl triazine ultraviolet light absorber (TZN UVA) is a 2-(2′-hydroxyphenyl)-1,3,5-triazine compound according to Formula (I): 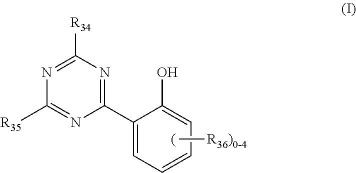
wherein
R₃₄ and R₃₅ are the same or different and are independently chosen from
a C₆-C₁₀ aryl group, wherein the C₆-C₁₀ aryl group is optionally substituted at from 1 to 3 substitutable positions with one or more group chosen from OH, halogen, C₁-C₁₂ alkyl, C₁-C₁₂ alkoxy, C₁-C₁₂ alkoxyester, C₂-C₁₂ alkanoyl, or phenyl, wherein the phenyl is optionally substituted at from 1 to 3 substitutable positions with one or more group chosen from: hydroxyl, halogen, C₁-C₁₂ alkyl, C₁-C₁₂ alkoxy, C₁-C₁₂ alkoxyester, or C₂-C₁₂ alkanoyl;
mono- or di-C₁-C₁₂ hydrocarbyl-substituted amino;
C₂-C₁₂ alkanoyl;
C₁-C₁₂ alkyl;
C₁-C₁₀ acyl; or
C₁-C₁₀ alkoxyl; and
R₃₆ is a substituent that is the same or different at from 0 to 4 positions of the phenoxy portion of Formula (I) and is independently chosen from hydroxyl, halogen, C₁-C₁₂ alkyl, C₁-C₁₂ alkoxy, C₁-C₁₂ alkoxyester, C₂-C₁₂ alkanoyl; phenyl; or C₁-C₁₂ acyl.

3. The stabilization composition according to claim 2, wherein the 2-(2′-hydroxyphenyl)-1,3,5-triazine compound is selected from the group consisting of:
4,6-bis-(2,4-dimethylphenyl)-2-(2-hydroxy-4-octyloxyphenyl)-s-triazine;
2-(4,6-diphenyl-1,3,5-triazin-2-yl-)-5-((hexyl)oxyl-phenol;
4,6-bis-(2,4-dimethylphenyl)-2-(2,4-dihydroxyphenyl)-s-triazine;
2,4-bis(2,4-dihydroxyphenyl)-6-(4-chlorophenyl)-s-triazine;
2,4-bis[2-hydroxy-4-(2-hydroxy-ethoxy)phenyl]-6-(4-chlorophenyl)-s-triazine;
2,4-bis[2-hydroxy-4-(2-hydroxy-4-(2-hydroxy-ethoxy)phenyl]-6-(2,4-dimethylphenyl)-s-triazine;
2,4-bis[2-hydroxy-4-(2-hydroxyethoxy)phenyl]-6-(4-bromophenyl)-s-triazine;
2,4-bis[2-hydroxy-4-(2-acetoxyethoxy)phenyl]-6-(4-chlorophenyl)-s-triazine;
2,4-bis(2,4-dihydroxyphenyl)-6-(2,4-dimethylphenyl)-s-triazine;
2,4-bis(4-biphenylyl)-6-[2-hydroxy-4-[(octyloxycarbonyl)ethylideneoxy]phenyl]-s-triazine;
2,4-bis(4-biphenylyl)-6-[2-hydroxy-4-(2-ethylhexyloxy)phenyl]-s-triazine;
2-phenyl-4-[2-hydroxy-4-(3-sec-butyloxy-2-hydroxypropyloxy)phenyl]-6-[2-hydroxy-4-(3-sec-amyloxy-2-hydroxypropyloxy)phenyl]-s-triazine;
2,4-bis(2,4-dimethylphenyl)-6-[2-hydroxy-4(-3-benzyloxy-2-hydroxypropyloxy)phenyl]-s-triazine;
2,4-bis(2-hydroxy-4-n-butyloxyphenyl)-6-(2,4-di-n-butyloxyphenyl)-s-triazine;
2,4-bis(2,4-dimethylphenyl)-6-[2-hydroxy-4-(3-nonyloxy-2-hydroxypropyloxy)-5-α-cumylphenyl]-s-triazine;
methylenebis-{2,4-bis(2,4-dimethylphenyl)-6-[2-hydroxy-4-(3-butyloxy-2-hydroxypropoxy)phenyl]-s-triazine};
methylene bridged dimer mixture bridged in the 3:5′,5:5′ and 3:3′ positions in a 5:4:1 ratio;
2,4,6-tris(2-hydroxy-4-isooctyloxycarbonyliso-propylideneoxy-phenyl)-s-triazine;
2,4,6,-tris(2-hydroxy-4-octyloxy-phenyl)-1,3,5-triazine;
2,4-bis(2,4-dimethylphenyl)-6-(2-hydroxy-4-hexyloxy-5-α-cumylphenyl)-s-triazine;
2-(2,4,6-trimethylphenyl)-4,6-bis[2-hydroxy-4-(3-butyloxy-2-hydroxypropyloxy)phenyl]-s-triazine;
2,4,6-tris[2-hydroxy-4-(3-sec-butyloxy-2-hydroxypropyloxy)-phenyl]-s-triazine;
mixture of 4,6-bis-(2,4-dimethylphenyl)-2-(2-hydroxy-4-(3-dodecyloxy-2-hydroxypropoxy)phenyl)-s-triazine and 4,6-bis-(2,4-dimethylphenyl)-2-(2-hydroxy-4-(3-tridecyloxy-2-hydroxypropoxy)phenyl)-s-triazine;
4,6-bis-(2,4-dimethylphenyl)-2-(2-hydroxy-4 (3-(2-ethylhexyloxy)-2-hydroxypropoxy)-phenyl)-s-triazine;
4,6-diphenyl-2-(4-hexyloxy-2-hydroxyphenyl)-s-triazine; and mixtures thereof.

4. The stabilization composition according to claim 1, wherein the hindered amine light stabilizer is selected from high molecular weight hindered amine light stabilizer having a weight average molecular weight of greater than 1000 g/mol.

5. The stabilization composition according to claim 4, wherein the hindered amine light stabilizer consists of the high molecular weight hindered amine light stabilizer.

6. The stabilization composition according to claim 4, wherein the high molecular weight hindered amine light stabilizer is selected from the group consisting of; a condensate of 1-(2-hydroxyethyl)-2,2,6,6-tetramethyl-4-hydroxypiperidine and succinic acid; 2,2,6,6-tetramethylpiperidin-4-yl stearate; a condensate of N,N′-bis(2,2,6,6-tetramethylpiperidin-4-yl)hexamethylenediamine and 4-tert-octylamino-2,6-dichloro-1,3,5-triazine; tetrakis(2,2,6,6-tetramethylpiperidin-4-yl)-1,2,3,4-butanetetracarboxylate; a condensate of N,N′-bis(2,2,6,6-tetramethylpiperidin-4-yl)hexamethylenediamine and 4-morpholino-2,6-dichloro-1,3,5-triazine; a condensate of N,N′-bis(2,2,6,6-tetramethylpiperidin-4-yl)hexamethylenediamine and 4-morpholino-2,6-dichloro-1,3,5-triazine, methylated; a condensate of 2-chloro-4,6-bis(4-n-butylamino-2,2,6,6-tetramethylpiperidyl)-1,3,5-triazine and 1,2-bis(3-aminopropylamino)ethane; a condensate of 2-chloro-4,6-bis(4-n-butylamino-1,2,2,6,6-pentamethylpiperidyl)-1,3,5-triazine and 1,2-bis-(3-aminopropylamino)ethane; a condensate of N,N′-bis(2,2,6,6-tetramethylpiperidin-4-yl)hexamethylenediamine and 4-cyclohexylamino-2,6-dichloro-1,3,5-triazine; a condensate of 1,2-bis(3-aminopropylamino)ethane, 2,4,6-trichloro-1,3,5-triazine and 4-butylamino-2,2,6,6-tetramethylpiperidine; oxo-piperanzinyl-triazines; 1,2,3,4-butanetetracarboxylic acid, polymer with 2,2,6,6-tetramethyl-2,4,8,10-tetraoxaspiro[5.5]-undecane-3,9-diethanol, 1,2,2,6,6-pentamethyl-4-piperdinyl ester; 1,2,3,4-butanetetracarboxylic acid, polymer with 2,2,6,6-tetramethyl-2,4,8,10-tetraoxaspiro[5.5]-undecane-3,9-diethanol, 2,2,6,6-tetramethyl-4-piperdinyl ester; bis(1-undecanoxy-2,2,6,6-tetramethylpiperidin-4-yl) carbonate; a reaction product of 1-(2-hydroxyethyl)-2,2,6,6-tetramethyl-4-piperdinol and dimethylsuccinate; 2,2,4,4-tetramethyl-7-oxa-3,20-diazadispiro[5.1.11.2]heneicosan-21-one; 1H-Pyrrole-2,5-dione, 1-octadecyl-, polymer with (1-methylethenyl)benzene and 1-(2,2,6,6-tetramethyl-4-piperidinyl)-1H-pyrrole-2,5-dione; the reaction product of 7,7,9,9-tetramethyl-2-cycloundecyl-1-oxa-3,8-diaza-4-oxospiro[4.5]decane and epichlorohydrin; the condensate of N,N′-bis(2,2,6,6-tetramethylpiperidin-4-yl)hexamethylenediamine and 4-cyclohexylamino-2,6-dichloro-1,3,5-triazine; the condensate of 1,2-bis(3-aminopropylamino)ethane, 2,4,6-trichloro-1,3,5-triazine and 4-butylamino-2,2,6,6-tetramethylpiperidine; the condensate of N,N′-bis(2,2,6,6-tetramethylpiperidin-4-yl)hexamethylenediamine and 4-morpholino-2,6-dichloro-1,3,5-triazine; the condensate of 2-chloro-4,6-bis(4-n-butylamino-2,2,6,6-tetramethylpiperidyl)-1,3,5-triazine and 1,2-bis(3-aminopropylamino)ethane; the condensate of 2-chloro-4,6-bis(4-n-butylamino-1,2,2,6,6-pentamethylpiperidyl)-1,3,5-triazine and 1,2-bis-(3-aminopropylamino)ethane; 2-[(2-hydroxyethyl)amino]-4,6-bis[N-(1-cyclohexyloxy-2,2,6,6-tetramethylpiperidin-4-yl)butylamino-1,3,5-triazine; the condensate of 1-(2-hydroxyethyl)-2,2,6,6-tetramethyl-4-hydroxypiperidine and succinic acid; the condensate of N,N′-bis(2,2,6,6-tetramethylpiperidin-4-yl)hexamethylenediamine and 4-tert-octylamino-2,6-dichloro-1,3,5-triazine; copolymer of methylmethacrylate with ethyl acrylate and 2,2,6,6-tetramethylpiperidin-4-yl acrylate; copolymer of mixed C₂₀ to C₂₄ alpha-olefins and (2,2,6,6-tetramethylpiperidin-4-yl) succinimide; 1,2,3,4-butanetetracarboxylic acid, polymer with β,β,β′,β′-tetramethyl-2,4,8,10-tetraoxaspiro[5.5]undecane-3,9-diethanol, 1,2,2,6,6-pentamethyl-4-piperidinyl ester; 1,2,3,4-butanetetracarboxylic acid, polymer with β,β,β′,β′-tetramethyl-2,4,8,10-tetraoxaspiro[5.5]undecane-3,9-diethanol, 2,2,6,6-tetramethyl-4-piperidinyl ester copolymer; and mixtures thereof.

7. The stabilization composition according to claim 1, wherein the hindered phenol antioxidant is chosen from: (1,3,5-tris(4-t-butyl-3-hydroxy-2,6-dimethylbenzyl)-1,3,5-triazine-2,4,6-(1H,3H,5H)-trione; 1,3,5-tris(3,5-di-tert-butyl-4-hydroxybenzyl)-1,3,5-triazine-2,4,6 (1H,3H,5H)-trione; 1,1,3-tris(2′-methyl-4′-hydroxy-5′-t-butylphenyl)butane; triethylene glycol bis[3-(3-t-butyl-4-hydroxy-5-methylphenyl)propionate]; 4,4′-thiobis(2-t-butyl-5-methylphenol); 2,2′-thiodiethylene bis[3-(3-t-butyl-4-hydroxyl-5-methylphenyl)propionate]; octadecyl 3-(3′-t-butyl-4′-hydroxy-5′-methylphenyl)propionate; tetrakismethylene(3-t-butyl-4-hydroxy-5-methylhydrocinnamate)methane; N,N′-hexamethylene bis[3-(3-t-butyl-4-hydroxy-5-methylphenyl)propionamide]; di(4-tertiarybutyl-3-hydroxy-2,6-dimethyl benzyl) thiodipropionate; and octadecyl 3,5-di-(tert)-butyl-4-hydroxyhydrocinnamate.

8. The stabilization composition according to claim 1, wherein the organic phosphite or phosphonite is chosen from: triphenyl phosphite; diphenyl alkyl phosphites; phenyl dialkyl phosphites; trilauryl phosphite; trioctadecyl phosphite; distearyl pentaerythritol phosphite; tris(2,4-di-tert-butylphenyl) phosphite; tris(nonylphenyl) phosphite; a compound of formulae (A), (B), (C), (D), (E), (F), (G), (H), (J), (K) and (L): 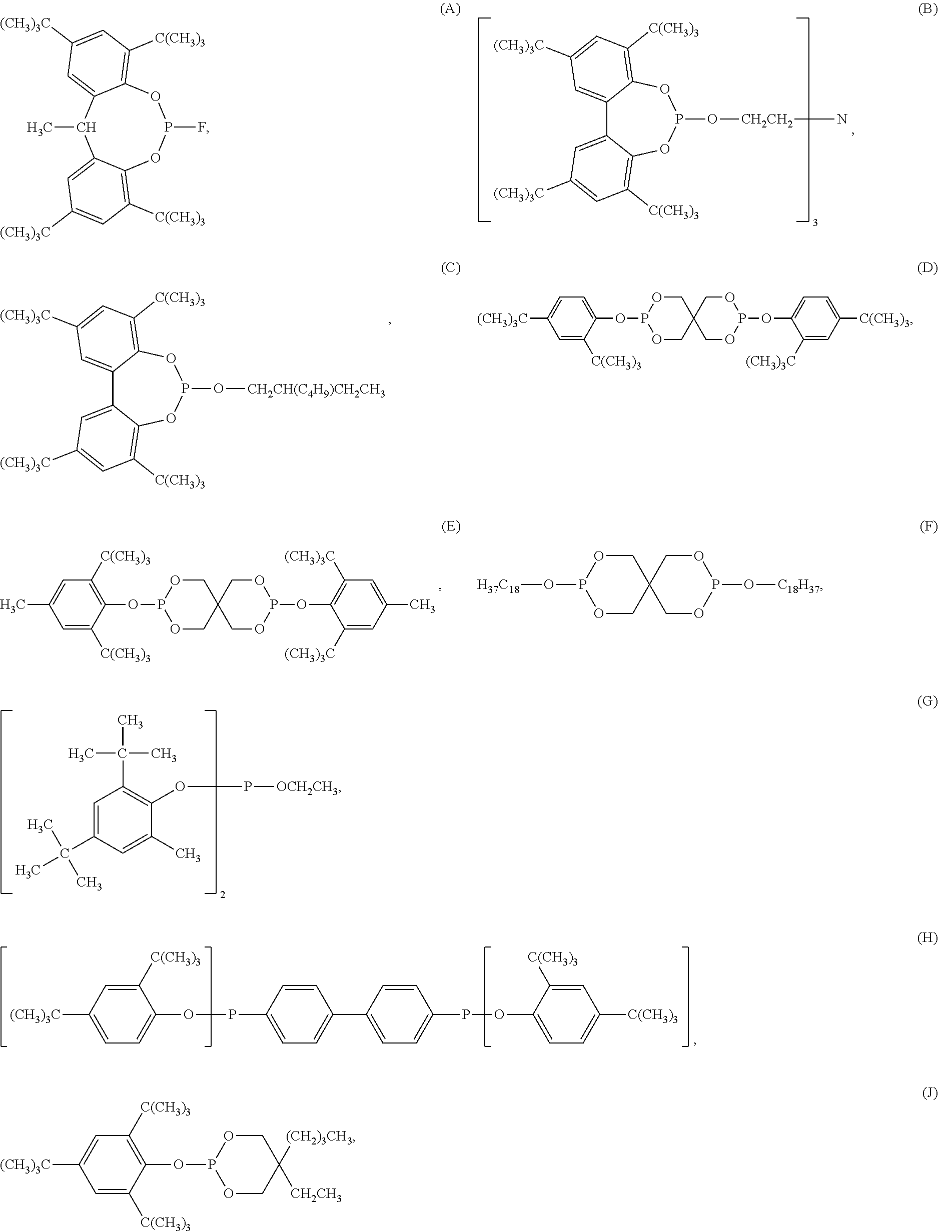 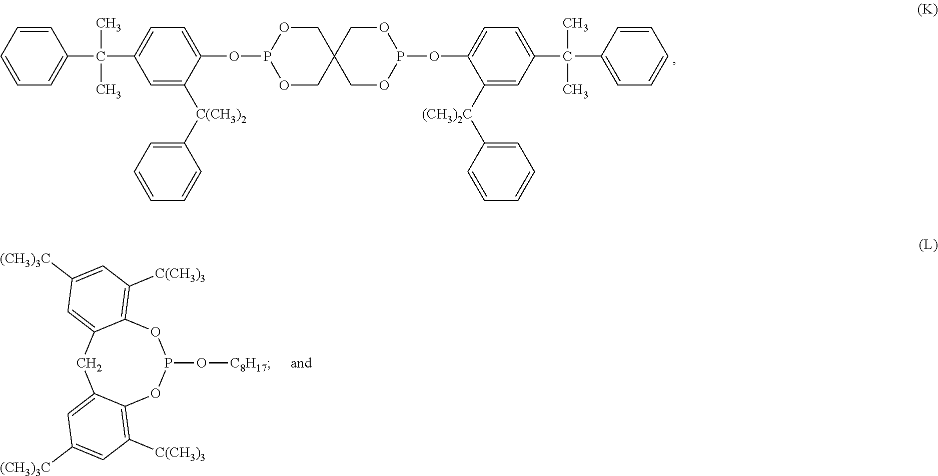
2-butyl-2-ethyl-1,3-propanediol 2,4,6-tri-t-butylphenol phosphite, bis-(2,6-di-t-butyl-4-methlphenyl) pentaerythritol diphosphite, 2-butyl-2-ethyl-1,3-propanediol 2,4-di-cumylphenol phosphite, 2-butyl-2-ethyl-1,3-propanediol 4-methyl-2,6-di-t-butylphenol phosphite, and bis-(2,4,6-tri-t-butyl-phenyl) pentaerythritol diphosphite, tris(2,4-di-tert-butylphenyl)phosphite (IRGAFOS® 168); bis(2,4-dicumylphenyl pentaerythritol diphosphite (DOVERPHOS® S9228); and tetrakis(2,4-di-tert-butylphenyl)4,4′-biphenylene-diphosphonite (IRGAFOS® P-EPQ).

9. The stabilization composition according to claim 1, which further comprises a co-stabilizer hindered benzoate or benzamide compound according to Formula (VII): 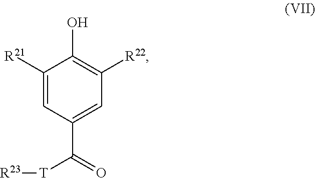
wherein
each of R₂₁ and R₂₂ is independently chosen from a C₁-C₁₂ alkyl;
T is chosen from O or NR²⁴, where R₂₄ is H or a C₁-C₃₀ hydrocarbyl; and
R₂₃ is H or a C₁-C₃₀ hydrocarbyl.

10. The stabilization composition according to claim 9, wherein the hindered benzoate compound is selected from the group consisting of 2,4-di-tert-butylphenyl-3,5-di-tert-butyl-4-hydroxybenzoate; hexadecyl-3,5-di-tert-butyl-4-hydroxybenzoate; octadecyl-3,5-di-tert-butyl-4-hydroxybenzoate; octyl-3,5-di-tert-butyl-4-hydroxybenzoate; decyl-3,5-di-tert-butyl-4-hydroxybenzoate; dodecyl-3,5-di-tert-butyl-4-hydroxybenzoate; tetradecyl-3,5-di-tert-butyl-4-hydroxybenzoate; behenylyl-3,5-di-tert-butyl-4-hydroxybenzoate; 2-methyl-4,6-di-tert-butylphenyl-3,5-di-tert-butyl-4-hydroxybenzoate; butyl-3-[3-t-butyl-4-(3,5-di-t-butyl-4-hydroxybenzoyloxy)phenyl]propionate; and mixtures thereof.

11. The stabilization composition according to claim 1, which further comprises a UV absorber ultraviolet light absorber (UVA) selected from the group consisting of orthohydroxybenzophenones; orthohydroxyphenyl benzotriazoles; benzoxazinone; oxanilides; cyanoacrylates; and mixtures thereof;

12. The stabilization composition according to claim 11, wherein the orthohydroxybenzophenone compound is selected from the group consisting of 2-hydroxy-4-methoxybenzophenone; 2,2′-dihydroxy-4-methoxybenzophenone; 2-hydroxy-4-octyloxybenzophenone; 2,2′-dihydroxy-4,4′-di-methoxybenzophenone; 2,2′-dihydroxybenzophenone; 2,2′,4,4′-tetrahydroxybenzophenone; 2,2′-dihydroxy-4,4′-dimethoxybenzophenone; 2,2′-dihydroxy-4,4′-diethoxybenzophenone; 2,2′-dihydroxy-4,4′-dipropoxybenzophenone; 2,2′-dihydroxy-4,4′-dibutoxybenzophenone; 2,2′-dihydroxy-4-methoxy-4′-ethoxybenzophenone; 2,2′-dihydroxy-4-methoxy-4′-propoxybenzophenone; 2,2′-dihydroxy-4-methoxy-4′-butoxybenzophenone; 2,2′-dihydroxy-4-ethoxy-4′-propoxybenzophenone; 2,2′-dihydroxy-4-ethoxy-4′-butoxybenzophenone; 2,3′-dihydroxy-4,4′-dimethoxybenzophenone; 2,3′-dihydroxy-4-methoxy-4′-butoxybenzophenone; 2-hydroxy-4,4′,5′-trimethoxybenzophenone; 2-hydroxy-4,4′,6′-tributoxybenzophenone; 2-hydroxy-4-butoxy-4′,5′-dimethoxybenzophenone; 2-hydroxy-4-ethoxy-2′,4′-dibutylbenzophenone; 2-hydroxy-4-propoxy-4′,6′-dichlorobenzophenone; 2-hydroxy-4-propoxy-4′,6′-dibromobenzophenone; 2,4-dihydroxybenzophenone; 2-hydroxy-4-ethoxybenzophenone; 2-hydroxy-4-propoxybenzophenone; 2-hydroxy-4-butoxybenzophenone; 2-hydroxy-4-methoxy-4′-methylbenzophenone; 2-hydroxy-4-methoxy-4′-ethylbenzophenone; 2-hydroxy-4-methoxy-4′-propylbenzophenone; 2-hydroxy-4-methoxy-4′-butylbenzophenone; 2-hydroxy-4-methoxy-4′-tertiary-butylbenzophenone; 2-hydroxy-4-methoxy-4′-chlorobenzophenone; 2-hydroxy-4-methoxy-2′-chlorobenzophenone; 2-hydroxy-4-methoxy-4′-bromobenzophenone; 2-hydroxy-4,4′-dimethoxybenzophenone; 2-hydroxy-4,4′-dimethoxy-3-methylbenzophenone; 2-hydroxy-4,4′-dimethoxy-2′-ethylbenzophenone; 2-hydroxy-4,4′,5′-trimethoxybenzophenone; 2-hydroxy-4-ethoxy-4′-methylbenzophenone; 2-hydroxy-4-ethoxy-4′-ethylbenzophenone; 2-hydroxy-4-ethoxy-4′-propylbenzophenone; 2-hydroxy-4-ethoxy-4′-butylbenzophenone; 2-hydroxy-4-ethoxy-4′-methoxybenzophenone; 2-hydroxy-4,4′-diethoxybenzophenone; 2-hydroxy-4-ethoxy-4′-propoxybenzophenone; 2-hydroxy-4-ethoxy-4′-butoxybenzophenone; 2-hydroxy-4-ethoxy-4′-chlorobenzophenone; 2-hydroxy-4-ethoxy-4′-bromobenzophenone; and mixtures thereof.

13. The stabilization composition according to claim 11, wherein the orthohydroxyphenyl benzotriazole compound is selected from the group consisting of 2-(2′-hydroxy-5′-methylphenyl)-benzotriazole; 2-(2′-hydroxy-5′-tert-butylphenyl)benzotriazole; 2-(2′-hydroxy-3′-methyl-5′-tert-butylphenyl)-benzotriazole; 2-(2′-hydroxy-5′-cyclohexylphenyl)-benzotriazole; 2-(2′-hydroxy-3′,5′-dimethylphenyl)-benzotriazole; 2-(2′-hydroxy-5′-tert-butylphenyl)-5-chloro-benzotriazole; 2-(2′-hydroxy-5-tert-octylphenyl)-2H-benzotriazole; 2-(2′-hydroxy-5-octylphenyl)-2H-benzotriazole; 2-(3′,5′-di-tert-butyl-2′-hydroxyphenyl)-5-chlorobenzotriazole; 2-(3′-tert-butyl-5′-methyl-butyl-2′hydroxyphenyl)-5-chlorobenzotriazole; 2-(3′,5′-di-tert-amyl-2′-hydroxyphenyl)benzotriazole; 2-(3′,5′-bis(α,α-dimethylbenzyl)-2′-hydroxyphenyl)benzotriazole; 2-(3′-tert-butyl-2′-hydroxy-5′-(2-octyloxycarbonylethyl)phenyl)benzotriazole; 2,2′-methylene-bis[4-(1,1,3,3-tetramethylbutyl)-6-benzotriazole-2-ylphenol]; the transesterification product of 2-[3′-tert-butyl-5′-(2-methoxycarbonylethyl)-2′-hydroxyphenyl]-2H-benzotriazole with polyethylene glycol 300; 2-[2′-hydroxy-3′-(α,α-dimethylbenzyl)-5′-(1,1,3,3-tetramethyl-butyl)phenyl]benzotriazole; 5-trifluoromethyl-2-(2-hydroxy-3-α-cumyl-5-tert-octylphenyl)-2H-benzotriazole; 2-(2′-hydroxy-5′-(2-hydroxyethyl)phenyl)benzotriazole; 2-(2′-hydroxy-5′-(2-methacryloyloxyethyl)phenyl)benzotriazole; 2-(3′-tert-butyl-5′-methyl-2′-hydroxyphenyl)-5-chloro-benzotriazole; 2-(3′-sec-butyl-5′-tert·butyl-2′-hydroxyphenyl)-benzotriazole; 2-(3′,5′-di-tert-butyl-2′-hydroxyphenyl)-benzotriazole; 2-(5′-tert-octyl-2′-hydroxyphenyl)-benzotriazole; 2-(3′-dodecyl-5′-methyl-2′-hydroxyphenyl)-benzotriazole; 2-(3′-tert-butyl-5′-(2-octyloxycarbonylethyl)-2′-hydroxyphenyl)-5-chlorobenzotriazole; 2-(5′-methyl-2′-hydroxyphenyl)-benzotriazole; 2-(5′-tert-butyl-2′-hydroxyphenyl)-benzotriazole; 2-(2′-hydroxy-3′-di-tert-butylphenyl)-benzotriazole; and mixtures thereof.

14. The stabilization composition according to claim 11, wherein the UV absorber benzoxazinone compound is selected from the group consisting of 2-methyl-3,1-benzoxazin-4-one; 2-butyl-3,1-benzoxazin-4-one; 2-phenyl-3,1-benzoxazin-4-one; 2-(1- or 2-naphthyl)-3,1-benzoxazin-4-one; 2-(4-biphenyl)-3,1-benzoxazin-4-one; 2-p-nitrophenyl-3,1-benzoxazin-4-one; 2-m-nitrophenyl-3,1-benzoxazin-4-one; 2-p-benzoylphenyl-3,1-benzoxazin-4-one; 2-p-methoxyphenyl-3,1-benzoxazin-4-one; 2-O-methoxyphenyl-3,1-benzoxazin-4-one; 2-cyclohexyl-3,1-benzoxazin-4-one; 2-p-(or m-)phthalimidephenyl-3,1-benzoxazin-4-one; N-phenyl-4-(3,1-benzoxazin-4-one-2-yl)phthalimide; N-benzoyl-4-(3,1-benzoxazine-4-one-2-yl)aniline; N-benzoyl-N-methyl-4-(3,1-benzoxazin-4-one-2-yl)-aniline; 2-[p-(N-phenylcarbamonyl)phenyl]-3,1-benzoxazin-4-one; 2-[p-(N-phenyl N-methylcarbamoyl)phenyl]-3,1-benzoxazin-4-one; 2,2′-bis(3,1-benzoxazin-4-one); 2,2′-ethylenebis(3,1-benzoxazin-4-one); 2,2′-tetramethylenebis(3,1-benzoxazin-4-one); 2,2′-hexamethylenebis(3,1-benzoxazin-4-one); 2,2′-decamethylenebis(3,1-benzoxazin-4-one); 2,2′-p-phenylenebis(3,1-benzoxazin-4-one); 2,2′-m-phenylenebis(3,1-benzoxazin-4-one); 2,2′-(4,4′-diphenylene)bis(3,1-benzoxazin-4-one); 2,2′-(2,6- or 1,5-naphthalene)bis(3,1-benzoxazin-4-one); 2,2′-(2-methyl-p-phenylene)bis(3,1-benzoxazin-4-one); 2,2′-(2-nitro-p-phenylene)bis(3,1-benzoxazin-4-one); 2,2′-(2-chloro-p-phenylene)bis(3,1-benzoxazin-4-one); 2,2′-(1,4-cyclohexylene)bis(3,1-benzoxazin-4-one); N-p-(3,1-benzoxazin-4-on-2-yl)phenyl; 4-(3,1-benzoxazin-4-on-2-yl)phthalimide; N-p-(3,1-benzoxazin-4-on-2-yl)benzoyl; 4-(3,1-benzoxazin-4-on-2-yl)aniline; 1,3,5-tri(3,1-benzoxazin-4-on-2-yl)benzene; 1,3,5-tri(3,1-benzoxazin-4-on-2-yl)naphthalene; and 2,4,6-tri(3,1-benzoxazin-4-on-2-yl)naphthalene.

15. The stabilization composition according to claim 1, which further comprises a co-additive selected from the group consisting of nucleating agents, fillers, thioesters, hydroxylamines, metallic stearates, metal oxides, reinforcing agents, plasticizers, lubricants, rheology agents, catalysts, leveling agents, optical brighteners, anti-static agents, blowing agents, flame retardants, and mixtures thereof.

16. The stabilization composition according to claim 1, wherein random polypropylene copolymer comprises 10 wt % to 99.99 wt % of the total weight of the composition for the polymeric front sheet.

17. The stabilization composition according to claim 1, wherein the total stabilizers content is from 0.01 wt % to 10 wt % of the total weight of the composition for the polymeric front sheet.

18. A stabilized polymeric front sheet of a photovoltaic cell comprising the stabilization composition according to claim 1.

19. A photovoltaic cell comprising the polymeric front sheet of a photovoltaic cell according to claim 18 and a photovoltaic element.

20. A method of making a stabilized polymeric front sheet of a photovoltaic cell comprising: extruding or molding the stabilization composition according to claim 1.
